(19) United States
(12) Patent Application Publication
(10) Pub. No.: US 2005/0028859 A1
(43) Pub. Date: Feb. 10, 2005

(54) Discharge-resistant outer-space solar generator

(76) Inventors: Guenther La Roche, Ottobrunn (DE); Brigitte Hoesselbarth, Grosskarolinenfeld (DE)

Correspondence Address: KENYON & KENYON, ONE BROADWAY, NEW YORK, NY, 10004, US

(21) Appl. No.: 10/343,575

(22) PCT Filed: Aug. 3, 2001
(86) PCT No.: PCT/EP01/09004

(30) Foreign Application Priority Data
Aug. 8, 2000 (DE) 100-54.776.1

(51) Int. Cl. H01L 25/00

(52) U.S. Cl. 136/244

(57) ABSTRACT

In a solar generator having several solar cells, which are mounted on a substrate so as to be spaced apart from each other, and are at least covered by protective layers on the side facing away from the substrate, conductive layers being deposited on the protective layers, and at least one gap being present between each solar cell and the solar cells adjacent to it, and at least a part of the longitudinal extension of at least one of the gaps per solar cell being filled up with a conductive adhesive between the adjacent solar cells, from the substrate to the conductive layers.

### FIELD OF THE INVENTION

The present invention relates to a discharge-resistant outer-space solar generator.

### BACKGROUND INFORMATION

Charged particles captured in the earth's magnetic field, corpuscular radiation of solar flares, and magnetic substorms cause solar generators of spacecraft, in particular of satellites, to be exposed to a continuously varying electron-proton stream, i.e., a stream of electrons and protons, which can amount to several nA/cm². In particular, the electrons, which are considerably more frequent due to their velocity, impart a negative charge to spacecraft for which suitable protective measures have not been taken.

The solar generator conductively connected with, inter alia, the spacecraft body assumes the potential of the spacecraft. Protective, glass solar-cell covers are mostly mounted on the solar generator in an electrically insulated manner. In addition to being a function of their conductivity, their charge is a function of the incident particle stream and the electrons generated by the photoelectric effect and secondary electron emission. In general, inverted charges having voltages up to greater than 1000 V are generated on the glass covers, which are discharged in regular intervals onto, inter alia, the solar cells that are connected to the mass of the satellite. The sparks generated ionize the solar-cell material, which can lead to a relatively long-lasting arc discharge, when a suitably strong electric field accelerates the released electrons and the discharge is maintained by impact ionization. The required electric field can be formed by, e.g. the potential difference of two adjacent solar cells, when high operating voltages are attained by, e.g., a U-shaped configuration of the solar cells.

Such a spontaneous discharge can generate very high temperatures that destroy materials. Thus, plastic films or sheets used to provide insulation from a solar-generator substrate can be carbonized and produce a conductive connection between the solar cells. This conductive connection does allow the discharge to be extinguished, but simultaneously short-circuits the solar cells for a short time, so that the result can be a malfunction of all the solar-generator circuits.

The cause of the short-circuits is the primary discharge of the glass covers to the solar cells. This primary discharge can be prevented by making the glass covers conductive and electrically connecting them to the mass of the solar generator, either directly or via the solar cells. In particular, a thin, optically adapted layer of indium-tin oxide (ITO) on the outside has proved to be successful for the glass covers. However, the connection of this conductive layer to the solar-generator structure is problematic, because it is either too costly or not sufficiently reliable. Several methods (tab welding, straight or helically shaped metal wire connection, pig tail interconnector plus conductive adhesive) were described by J. W. Koch in “A low cost anticharging connection system for solar generators and its application on ASPERA solar array”, Proceedings of the European Space Power Conference, Madrid, Spain, 2-6 Oct. 1989, ESA SP-294, page 587. Further solutions include the method described in German Published Patent Application No. 197 11 319 of connecting the glass covers in a conductive manner, via the corners, using metal pads and conductive adhesive, which was insulated from the solar cells by filling up the cell gaps with insulating adhesive; or the method described in International Published Patent Application No. WO 99/38217 of vapor-depositing a very thin gold layer or the ITO layer on the cell edges and glass-cover edges.

As described in U.S. Pat. No. 5,919,316, the charges are conducted from the glass cover to the cell contact or cell connector, using either a wrap-around technique of a conductive ITO layer (i.e., the ITO layer partially surrounds the glass cover), or vapor-deposition of a layer onto the edges of the glass cover, which is connected to the cell connector with the aid of a conductive epoxy-resin bulb. In this case, the problem is how the contact is made with the cell electrode, i.e., how the epoxy-resin bulb is produced without short-circuiting the cell or rendering the cell connector unable to survive. In addition, wrap-around technology is expensive to implement.

The description contained in European Published Patent Application No. 0 938 141 does not prevent a primary discharge, but reduces the formation of a secondary arc discharge. In this context, a non-conductive filler is provided in the cell gaps.

All of the methods are relatively complicated and cost-intensive.

Therefore, it is an object of the present invention to provide a solar generator and a manufacturing method, which allow the manufacturing to be performed in a simple manner and furthermore ensure that primary discharges are effectively prevented.

### SUMMARY

The above object may be achieved by providing a solar generator and a method for manufacturing a solar generator as described herein.

The solar generator of the present invention has several solar cells mounted on a carrier material or substrate so as to be spaced apart from each other. Thus, gaps are provided between adjacent solar cells, the number of gaps being a function of how many adjacent solar cells surround a particular solar cell. At least the sides of the solar cells facing away from the substrate are covered by covering or protective layers. Such protective layers are particularly arranged to insulate and may be made of glass or another suitable material. Just one protective layer may be provided per solar cell, but also several protective layers are possible. Conductive layers, which cover at least a part of the protective layer, are deposited onto or applied to the protective layers. They may cover them, for example, in the form of individual conductors or a lattice. In addition, it is possible to provide complete coverage, while the function of the solar cell is impaired comparatively little. The present invention provides for at least one of the gaps per solar cell being filled with a conductive adhesive, which extends from the substrate to the conductive layers. The adhesive may not have to fill the gap up completely in the direction of the longitudinal extension of the gap, i.e., in a direction parallel to the solar-cell edges forming the gap. It may be sufficient for just a subsection of the gap to be filled in this direction. It may only be ensured that the conductive adhesive is connected to an edge of the solar cell and to the conductive layers, in order to produce a conductive connection between these two. However, it is possible that the filling-up of the spaces may allow this conductive connection between solar cell and conductive layer to be produced for two solar cells simultaneously.

As previously described, the conductive layers may cover at least subsections of the protective-layer surfaces facing away from the solar cells. However, the conductive layers may also cover at least subsections of the edge surfaces of the protective layers. This may simplify the manufacturing of the contact with the conductive adhesive, since a larger contact surface is present on the side of the protective layers, as well. On the side of the solar cells, the contact is already established via the edge surfaces, i.e., as a rule, through or via the semiconductor material of the solar cell (a specially arranged electrode may not have to be provided for this).

Any suitable material may be provided for the conductive adhesive. It may take the form of a silicone adhesive enriched with conductive material.

The following steps are performed in the method of the present invention for manufacturing a solar generator, in which solar cells spaced apart from each other by gaps are mounted on a substrate, where at least the sides of the solar cells facing away from the substrate are covered by protective layers, and conductive layers are deposited on the protective layers:
fixing the solar cells on the side of the protective layers, the fixing being able to be accomplished by a suitable fixing device, such as a clamping device or a vacuum device, or using a suitable adhesive surface, etc.;
filling up at least a part of at least one gap per solar cell with a conductive adhesive, in the direction of the longitudinal extension of the gaps, from the protective-layer surfaces facing away from the solar cells to the solar-cell surfaces facing away from the protective layers, so that the conductive adhesive is therefore connected to the protective-layer surfaces facing away from the solar cells, and to the side edges of the solar cells, but the gap does not have to be completely filled up in the direction parallel to the solar-cell side edges forming the gap; and
applying an adhesive to the solar-cell surfaces facing away from the protective layers;
applying a substrate to the solar-cell surfaces facing away from the protective layers.

The application of the adhesive to the solar-cell surfaces facing away from the protective layers and the application of the conductive adhesive may be accomplished, using any suitable technique, a screen or screen printing technique, e.g., being used for at least the adhesive on the solar-cell surfaces facing away from the protective layers, and being used for the conductive adhesive as well. However, suitable dosing devices may also be used as an alternative. In this context, the filling-in of the gaps with a conductive adhesive and the application of the adhesive to the surfaces of the solar cells may be accomplished in a single working step, i.e., the same adhesive is used for both purposes, and adhesive may only be applied once to the set-up, e.g., using a suitable screen-printing technique.

An exemplary embodiment of the present invention is explained below with reference to FIGS. 1 and 2.

### BRIEF DESCRIPTION OF THE DRAWINGS

FIG. 1 is a cross-sectional view of a solar generator according to the present invention.

FIG. 2 is a plan view of the solar generator illustrated in FIG. 1.

### DETAILED DESCRIPTION

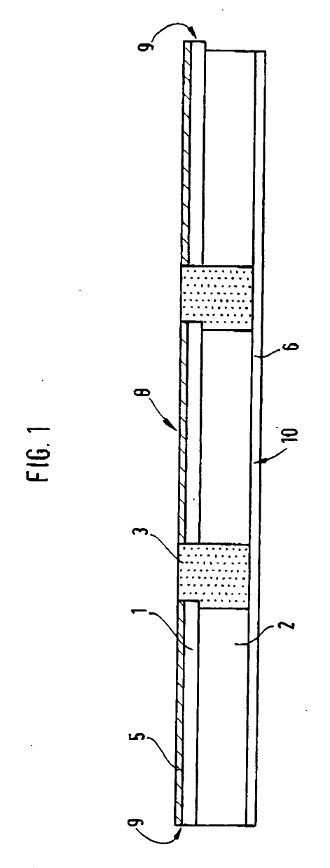

FIG. 1 is a cross-sectional view of a solar generator, where several solar cells 2 are arranged on a substrate 6. These are bonded to the substrate on lower surface 10 in FIG. 1. Attached to the other side of solar cells 2 are glass covers 1, whose upper surfaces 8 are at least partially covered by a conductive layer 5. In FIG. 1, lateral surfaces 9 of glass covers 1 are illustrated without a coating of a conductive layer 5. However, these edge surfaces 9 may also be partially covered by a conductive layer 5, which is conductively connected to conductive layers 5 on upper surface 8. A conductive adhesive 3 is introduced between solar cells 2, the conductive adhesive extending from substrate 6 to the level of the conductive layers 5 on upper surface 8. It, i.e., the adhesive, fills in the gaps between solar cells 2 in such a manner, that, in each case, adjacent solar cells 2, their glass covers 1, and the conductive layers 5 on the glass covers are interconnected.

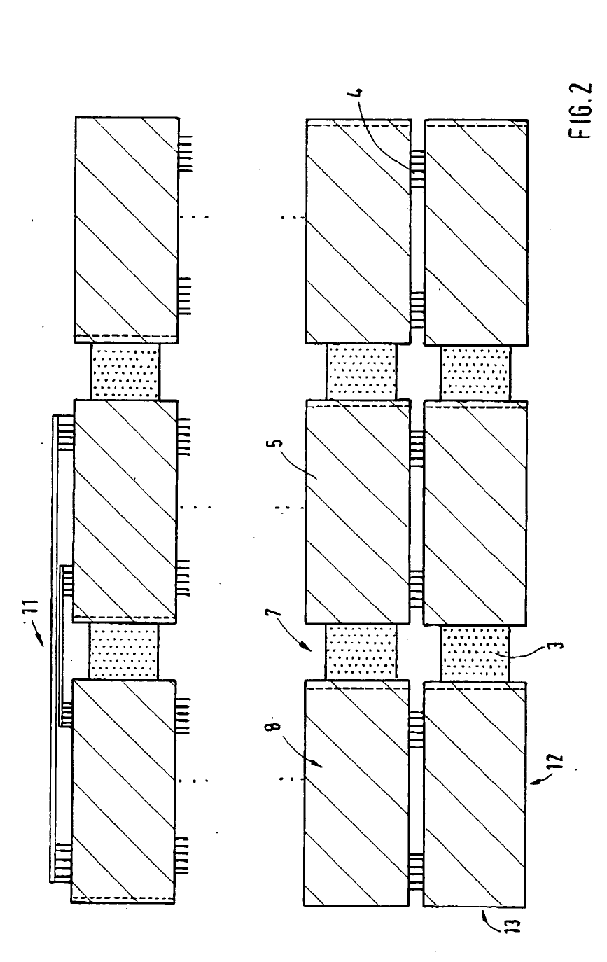

FIG. 2 is a plan view of the solar generator illustrated in FIG. 1. In this context, the gaps 7 between individual solar cells 2 may not have to be completely filled in with conductive adhesive 3 in the direction parallel to lateral surfaces 9 of the glass covers. In addition, not all of the gaps between adjacent solar cells 2 have to be filled in with a conductive adhesive 3. It is sufficient that, per solar cell, at least one gap 7 to or leading to an adjacent solar cell is filled in with a conductive adhesive 3. Conductive layers 5 on glass covers 1 are schematically illustrated in FIG. 2 so that they cover the complete upper surface of the glass covers. However, this may only be useful when these layers 5 are sufficiently transparent. As an alternative, an anti-reflection layer deposited on or applied to the glass cover may also be used as a conductive layer. In other cases, one may provide for conductive layers 5 only taking the form of individual conductors or a lattice or lattices on glass covers 1.

In FIG. 2, solar cells 2 are arranged in rows 13 and columns 12. In the example embodiment of the present invention illustrated in FIG. 2, the solar cells 2 of a column 12 are interconnected by customary cell connectors 4 in the form of a series circuit. Points indicate that more than just the three rows 13 represented may be provided. As illustrated in FIG. 2, individual columns 12 may be conductively interconnected at their ends, as well. But columns 12 may also be independent of each other, so that only the solar cells 2 within a column 12 are connected in the form of a series circuit. However, adjacent columns 12 may be connected in countercurrent. To this end, connectors 11, which produce a U-shaped interconnection of solar cells 2 and columns 12 of solar cells 2, are schematically illustrated in FIG. 2. Therefore, the solar cells 2 of middle column 12 in FIG. 2 are connected in series with the solar cells 2 of left column 12, though in reverse order. In this manner, the potential difference between solar cells 2 of adjacent columns 12 increases towards bottom row 13 in FIG. 2. In this case, a high-resistance, conductive adhesive 3 may therefore be provided between these columns 12, in order to prevent a short-circuit between columns 12.

In the case of a typical electron current of 10 nA/cm², an, e.g., 25 cm² glass cover 1 may have to be “grounded” across a resistance of 400 M to keep the charge of glass cover 1 under 100 V. Glass covers typically have specific resistances of 10¹⁶ cm. This does not prevent the charging of glass covers 1. A high-resistance conductor, e.g., in the form of an adhesive 3, which has low conductivity and connects glass cover 1 with subjacent and adjacent solar cells 2, is introduced into the gap 7 between two adjacent cells 2. If one fills up the long gap 7 between two U-shaped cell chains having an operational voltage of 100 V, with a filler 3 (silicone adhesive), e.g., having a specific resistance of 10⁹ cm, then the charge of the glass cover may always remain under 100 V, and the conductivity of filler 3 may only cause the module to lose approximately 10 uA, which may be negligible in the case of a typical cell current of 1 A.

The present invention involves mixing a common silicone adhesive, e.g., Wacker RTV-S 695 or Dow Corning 93500, with conductive material such as carbon black or metal powder, so that the adhesive may have a sufficient conductivity of, e.g., 10⁻⁹-10⁻¹⁰ S/cm. While preparing to cement solar-cell modules to a panel structure in the form of substrate 6, solar cells 2 lie with the back side 10 up on, e.g., an adhesive film or sheet, which is sufficiently fixed in position, e.g., on a positioning plate or sheet. The adhesive for cementing solar cells 2 may be applied, for example, by a screen in a screen-printing process, and to be sure, in a manner allowing cell gaps 7 to remain free of adhesive. However, an intermediate step is inserted in front of this step, the intermediate step including the application of conductive adhesive 3, using, in this case, screen printing as well. For this purpose, a course screen is used, which may only allow adhesive to flow out at the cell gaps 7 that should be filled with conductive adhesive 3. The screen-printing technique allows the desired locations to be defined in a very precise manner. A small amount of overflow onto back side 10 of the cell may not have a negative effect. The conductive adhesive may be applied other than by screen printing, e.g., using a dosing device. It may be important that the adhesive flows down to glass covers 1, and that glass cover 1 and cell 2 are conductively interconnected.

Glass covers 1 do not have to be conductive at their edges, if conductive adhesive 3 reaches upper surface 8. However, at least a part of conductive layer 5 may also be pulled around the edge, onto lateral surface 9 of glass covers 1, which may be accomplished without a large amount of extra effort.

1. A solar generator having several solar cells (2), which are mounted on a carrier material (6) so as to be spaced apart from each other, and are at least covered by covering layers (1) on the side facing away from the substrate (6), conductive layers (5) being deposited on the protective layers (1), and at least one gap (7) being present between each solar cell (2) and the solar cells adjacent to it,
wherein at least a part of the longitudinal extension of at least one of the gaps (7) per solar cell (2) is filled up with a high-resistance, conductive adhesive (3) between the adjacent solar cells (2), from the substrate (6) to the conductive layers (5).

2. The solar generator as recited in claim 1,
wherein the conductive layers (5) cover at least subsections of the upper surfaces (8) of the protective layers (1) facing away from the solar cells (2).

3. The solar generator as recited in claim 2,
wherein the conductive layers (5) additionally cover at least subsections of the edge surfaces (9) of the protective layers (1).

4. The solar generator as recited in one of claims 1 through 3,
wherein the conductive adhesive (3) takes the form of silicone adhesive enriched with conductive material.

5. A method for manufacturing a solar generator having solar cells (2), which are mounted on a substrate (6), are spaced apart from each other by gaps (7), and are at least covered by protective layers (1) on the side facing away from the substrate (6); conductive layers (5) being deposited on the protective layers (1), and the method having the steps:
fixing the solar cells in position, on the side of the protective layers (1),
applying an adhesive to the upper surfaces (10) of the solar cells (2) facing away from the protective layers (1),
positioning a substrate (6) onto the upper surfaces (10) of the solar cells (2) facing away from the protective layers (1);
wherein, after the solar cells (2) are fixed in position, at least one gap (7) per solar cell (2) is at least partially filled up with a conductive adhesive (3) in the direction of the longitudinal extension of the gaps (7), from the upper surfaces (8) of the protective layers (1) facing away from the solar cells (2), to the upper surfaces (10) of the solar cells (2) facing away from the protective layers (1).

6. The method as recited in claim 5,
wherein the adhesive is applied by a screen technique.
